(19) United States
(12) Patent Application Publication
(10) Pub. No.: US 2024/0379335 A1
(43) Pub. Date: Nov. 14, 2024

(54) CALIBRATION APPARATUS FOR SENSOR DEVICE AND SYSTEM INCLUDING THE SAME

(71) Applicant: SAMSUNG ELECTRONICS CO., LTD., Suwon-si (KR)

(72) Inventors: Taijo Jeon, Suwon-si (KR); Jawon Ko, Suwon-si (KR); Jongwha Lee, Suwon-si (KR); Yunsong Jeong, Suwon-si (KR)

(21) Appl. No.: 18/396,254

(22) Filed: Dec. 26, 2023

(30) Foreign Application Priority Data
May 11, 2023 (KR) 10-2023-0061112
Oct. 31, 2023 (KR) 10-2023-0147693

(51) Int. Cl. H01J 37/32

(52) U.S. Cl. CPC H01J 37/32935; H01J 2237/24592

(57) ABSTRACT

The present disclosure relates to calibration apparatuses of sensor devices. An example calibration apparatus of a sensor device includes a housing providing a darkroom space by blocking light from the outside, a lighting unit installed in the darkroom space and configured to output light in a specific wavelength band, a stage on which the sensor device, configured to detect intensity of light output by the lighting unit in at least one measurement position, is mounted, the stage installed below the lighting unit in the darkroom space, and a control device configured to receive raw data including intensity of light measured by the sensor device. The control device generates calibration data for adjusting intensity of light measured at the at least one measurement position.

### CROSS-REFERENCE TO RELATED APPLICATION

This application claims benefit of priority to Korean Patent Application No. 10-2023-0061112, filed on May 11, 2023, and Korean Patent Application No. 10-2023-0147693, filed on Oct. 31, 2023, in the Korean Intellectual Property Office, the disclosure of which is incorporated herein by reference in its entirety.

### BACKGROUND

In a semiconductor processing apparatus for performing a semiconductor process using plasma, it may be necessary to accurately control a thickness and density of plasma formed on a process object, such as a wafer, to improve yield. To form a thickness and density of plasma to a desired level, control variables of the semiconductor processing device may be adjusted while observing the plasma through a viewing port of the semiconductor processing device prior to the semiconductor process. However, it may be difficult to accurately determine a thickness and density of the plasma by observing the plasma through the viewing port, and accordingly, a thickness and density of the plasma may not be accurately formed to desired values during an actual semiconductor process.

### SUMMARY

The present disclosure relates to a calibration apparatus which may improve performance of a sensor device inserted into a semiconductor processing apparatus and collecting raw data representing characteristics of plasma formed in the semiconductor processing apparatus before a semiconductor process is performed, and a system including the same.

In some implementations, a calibration apparatus of a sensor device includes a housing providing a darkroom space by blocking light from the outside; a lighting unit installed in the darkroom space and configured to output light in a specific wavelength band; a stage on which a sensor device configured to detect intensity of light output by the lighting unit in at least one measurement position is mounted, and installed below the lighting unit in the darkroom space; and a control device configured to receive raw data including intensity of light measured by the sensor device, wherein the control device generates calibration data for adjusting intensity of light measured in the at least one measurement position.

In some implementations, a calibration apparatus of a sensor device includes a lighting unit configured to output light of the same intensity to a plurality of measurement positions included in a sensor device, the sensor device including a lower substrate and an upper substrate opposing each other, a plurality of optical members configured to guide light entering the plurality of measurement positions formed on the upper substrate, and an optical detector configured to detect intensity of light guided by each of the plurality of optical members; a stage on which the sensor device is seated; and a control device communicatively connected to the sensor device and configured to receive raw data from the sensor device, the raw data including intensity of light measured by the sensor device in each of the plurality of measurement positions, wherein the control device is configured to generate calibration data such that intensities of light measured in the plurality of measurement positions are equalized.

In some implementations, a system includes a plurality of semiconductor process systems each including a semiconductor processing apparatus configured to form plasma and to perform a semiconductor process; a transfer system configured to transfer at least one sensor device to the plurality of semiconductor process systems; and a calibration apparatus including a housing providing a darkroom space therein and a lighting unit and a stage installed in the darkroom space, and configured to perform a calibration of reducing a characteristic deviation of a measurement position included in the at least one sensor device while the at least one sensor device is seated on the stage and the lighting unit outputs light.

### BRIEF DESCRIPTION OF THE DRAWINGS

The above and other aspects, features, and advantages in the example implementations will be more clearly understood from the following detailed description, taken in combination with the accompanying drawings.

FIG. 1 is a diagram illustrating an example of a semiconductor process system.

FIG. 2 is a diagram illustrating an example of a semiconductor processing apparatus.

FIGS. 3 and 4 are diagrams illustrating an example of a sensor device.

FIG. 5 is a block diagram illustrating an example of a sensor device.

FIGS. 6 to 8 are diagrams illustrating an example of a calibration apparatus.

FIG. 9 is a block diagram illustrating an example of a calibration apparatus.

FIGS. 10 and 11 are flowcharts illustrating operations of an example of a calibration apparatus.

FIGS. 12 to 15 are diagrams illustrating operations of an example of a calibration apparatus.

### DETAILED DESCRIPTION

Hereinafter, example implementations will be described as follows with reference to the accompanying drawings.

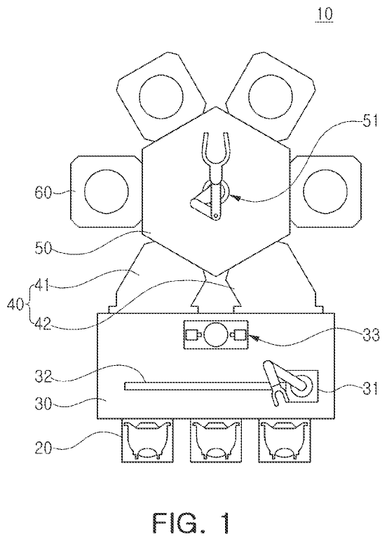

FIG. 1 is a diagram illustrating an example of a semiconductor process system.

Referring to FIG. 1, a semiconductor process system 10 according to an example implementation may include a wafer transfer device 30, a load-lock chamber 40, a transfer chamber 50 and a plurality of semiconductor processing apparatuses 60. For example, the wafer transfer device 30 may receive a wafer through a container such as a front open unified pod 20 (FOUP) in a line in which the semiconductor process system 10 is disposed. The wafer transfer device 30 may transfer wafers received through the FOUP 20 to the load-lock chamber 40 or may receive wafers for which a semiconductor process has been completed in the process chambers 60 from the load-lock chamber 40 and may store the wafers in the FOUP 20.

The wafer transfer device 30 may include a wafer transfer robot 31 having an arm for holding a wafer, a rail portion 32 for moving the wafer transfer robot 31, and an aligner 33 for aligning wafers. Assuming an operation of transferring wafers from the FOUP 20 to the load-lock chamber 40, the wafer transfer robot 31 may take out wafers stored in the FOUP 20 and may dispose the wafers on an aligner 33. In the aligner 33, wafers may align wafers in one predetermined direction by rotating the wafers. After wafer alignment is completed by the aligner 33, the wafer transfer robot 31 may take the wafer out of the aligner 33 and may transfer the wafers to the load-lock chamber 40.

The load-lock chamber 40 may include a loading chamber 41 connected to the wafer transfer device 30 and in which wafers entering the semiconductor processing apparatus 60 may temporarily stay for the semiconductor process, and an unloading chamber 42 in which wafers taken out of the process chamber 60 may temporarily stay after the process is completed. When the wafers aligned in the aligner 33 enter the loading chamber 41, the internal side of the loading chamber 41 may be depressurized to prevent external contaminants from entering.

The load-lock chamber 40 may be connected to the transfer chamber 50, and a plurality of semiconductor processing apparatuses 60 may be connected around the transfer chamber 50. In the transfer chamber 50, a wafer transfer robot 51 for transferring wafers between the load-lock chamber 40 and the plurality of process chambers 60 may be disposed. The wafer transfer robot 31 of the wafer transfer device 30 may be referred to as a first wafer transfer robot, and the wafer transfer robot 51 of the transfer chamber 50 may be referred to as a second wafer transfer robot.

Each of the plurality of semiconductor processing apparatuses 60 may perform a semiconductor process for a wafer. For example, a semiconductor process performed by the plurality of semiconductor processing apparatuses 60 may include a deposition process, an etching process, an exposure process, an annealing process, a polishing process, an ion implantation process, and the like.

To perform at least a portion of the aforementioned semiconductor processes, a plasma may be formed in at least one of the plurality of semiconductor processing apparatuses 60. The plasma may be formed on a wafer, a mask, and a mother substrate for displays, which may be objects of the semiconductor process, and yield of the process may vary depending on how the plasma is formed. Accordingly, prior to actually performing a semiconductor process in the semiconductor processing apparatuses 60, an operation of forming a plasma and analyzing characteristics thereof may be preceded.

In an example implementation, characteristics of plasma formed in semiconductor processing apparatuses 60 may be analyzed using a sensor device having a shape such as a wafer, a mask, and a mother substrate for a display as a process target. For example, the sensor device may include a plurality of optical members installed in different positions of a plurality of optical members and receiving light emitted from plasma, and an optical detector for detecting intensity of light transmitted by the plurality of optical members.

Intensity of light detected by the optical detector may be processed in the form of raw data, and a thickness and density of plasma may be analyzed using the raw data. Accordingly, control variables of the semiconductor processing apparatus 60 may be accurately determined such that plasma may be formed with a desired thickness, density, and distribution. However, since a plurality of optical members in the sensor device receive light from different plurality of measurement positions and transmit light to the optical detector, even when light of the same intensity enter each of a plurality of measurement positions, the issue in which the optical detector may detect intensity of light differently may occur. For example, intensity of light transmitted to an optical detector may vary due to a difference in lengths of the plurality of optical members connected to the plurality of measurement positions.

In an example implementation, to prevent the above issue, prior to inserting the sensor device into the semiconductor processing apparatus 60, a calibration operation may be performed. The calibration operation may include adjusting the sensor device such that the optical detector may detect intensity of light constantly when light of the same intensity enters each of a plurality of measurement positions included in the sensor device. Accordingly, characteristics of plasma generated in the semiconductor processing apparatuses 60 may be accurately analyzed using the sensor device, and yield of the semiconductor process performed in each of the semiconductor processing apparatuses 60 may be improved.

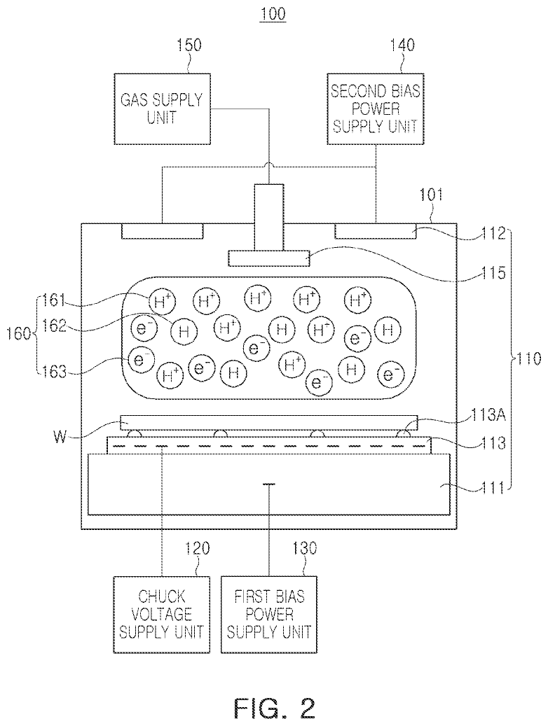

FIG. 2 is a diagram illustrating an example of a semiconductor processing apparatus.

The semiconductor processing apparatus 100 according to an example implementation may be configured as a device for performing a semiconductor process using plasma. The semiconductor processing apparatus 100 may include a chamber 110, a chuck voltage supply unit 120, a first bias power supply unit 130, a second bias power supply unit 140, and a gas supply unit 150.

The chamber 110 may include a housing 101, a first bias electrode 111, a second bias electrode 112, an electrostatic chuck 113, and a gas flow path 114. A process target for a semiconductor processing may be seated on the electrostatic chuck 113. In an example implementation illustrated in FIG. 2, the process target is illustrated as the wafer W, but the process target may be changed to a mother substrate for display, a mask, and the like.

As illustrated in FIG. 2, a plurality of protrusions 113A having a protrusion shape may be formed on an upper surface of the electrostatic chuck 113. The wafer W may be seated on the protrusion 113A, and accordingly, a space may be formed between the upper surface of the electrostatic chuck 113 and the wafer W. For example, a space between the upper surface of the electrostatic chuck 113 and the wafer W may be filled with helium gas for the purpose of cooling the wafer W.

In an example implementation, the wafer W may be fixed to the electrostatic chuck 113 by Coulomb force generated by a chuck voltage supplied to the electrostatic chuck 113 by a chuck voltage supply unit 120. For example, chuck voltage supply unit 120 may supply chuck voltage to an electrostatic chuck 113 in the form of a constant voltage, and the chuck voltage may range in the hundreds to thousands of volts.

Reactive gas may flow in through the gas flow path 114 to perform the semiconductor process. A first bias power supply unit 130 may supply first bias power to the first bias electrode 111 disposed below the electrostatic chuck 113, and the second bias power supply unit 140 may supply second bias power to the second bias electrode 112 disposed above the electrostatic chuck 113. Each of the first bias power supply unit 130 and the second bias power supply unit 140 may include a radio frequency (RF) power source for supplying bias power.

The plasma 160, including ions 161, radicals 162, and electrons 163 of reactive gas, may be formed in the space above the wafer W by the first bias power and the second bias power, and reactive gas may be activated by the plasma 160, such that reactivity may increase. For example, when the semiconductor processing apparatus 100 is configured as an etching device, by the first bias power supplied to the first bias electrode 111 by the first bias power supply unit 130, the reactive gas ions 161, the radicals 162 and the electrons 163 may be accelerated by the wafer W. At least a portion of the semiconductor substrate or layers included in the wafer W may be dry-etched by the ions 161, the radicals 162 and the electrons 163 of reactive gas.

Light may be emitted while particles such as the ions 161 are stabilized in the plasma 160, and a wavelength band of light emitted may differ depending on chemical species. Accordingly, by detecting intensity of light emitted from the plasma 160 in a predetermined wavelength band, characteristics such as density and thickness of plasma may be detected.

In an example implementation, instead of the wafer W on which an etching process and a deposition process using plasma 160 are performed, a separately manufactured sensor device may be disposed on the electrostatic chuck 113, and characteristics such as uniformity of plasma 160 may be analyzed using the raw data collected by the sensor device. The sensor device may include a plurality of optical members for receiving light emitted from the plasma 160 and an optical detector for measuring intensity of light transmitted by the plurality of optical members.

The plurality of optical members may be installed in a sensor device to receive light emitted from different measurement positions of the plasma 160, and an optical detector may detect intensity of light in a predetermined wavelength band. Accordingly, depending on the characteristics of a plurality of optical members and the optical detector, even when light of the same intensity enters measurement positions, the optical detector may detect intensity of light differently. In an example implementation, reliability of the sensor device may be secured by performing a calibration work on the sensor device in advance.

For example, a sensor device may be inserted into a calibration apparatus provided with an arm chamber space therein, and a calibration operation may be performed while the sensor device detects light output by a lighting unit installed on the sensor device. The lighting unit may operate such that light of the same intensity may enter each of the plurality of measurement positions included in the sensor device, and the calibration apparatus may determine whether intensity of light detected by the optical detector of the sensor device appears differently depending on the measurement positions, and may perform a calibration operation on the basis of the determination.

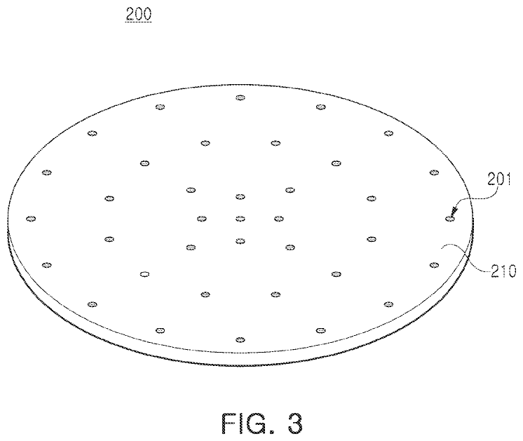

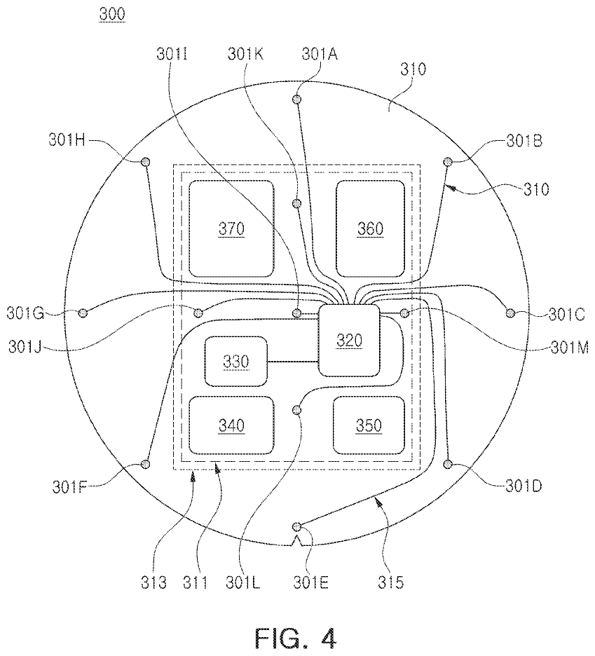

FIGS. 3 and 4 are diagrams illustrating an example of a sensor device.

Referring to FIG. 3, a sensor device 200 according to an example implementation may have the same shape as that of a process target inserted into a semiconductor processing apparatus. In an example implementation illustrated in FIG. 3, the sensor device 200 may have a wafer-like shape. However, the sensor device 200 may have a shape such as a mask substrate, a mother substrate for a display, and the like.

The sensor device 200 may include a body 210 and a plurality of light-receiving regions 201 formed in the body 210. External light may enter each of a plurality of light-receiving regions 201, and accordingly, a measurement position may be defined for each of the plurality of light-receiving regions 201. However, the sensor device 200 may include only one light-receiving region formed in the body 210. For example, when the sensor device 200 includes only a light-receiving region corresponding to one measurement position, the light-receiving region may be disposed in a center of the sensor device 200.

A hole may be formed in each of a plurality of light-receiving regions 201, and external light may enter through the hole. One of a plurality of optical members may be connected to the hole, and the plurality of optical members may guide light entering through the hole to an optical detector. The optical detector may detect intensity of light received through a plurality of optical members in a specific wavelength band.

For example, an optical detector may be disposed in the body 210 of the sensor device 200, and accordingly, at least a portion of a plurality of optical members connecting the optical detector to a plurality of light-receiving regions 201 may have different lengths. Accordingly, when light of the same intensity enter the plurality of light-receiving regions 201 due to a difference in lengths of a plurality of optical members, the optical detector may measure intensity of light differently for at least a portion of the light-receiving regions 201.

In an example implementation, a calibration operation for the sensor device 200 may be performed in advance. For example, light of the same intensity may be irradiated to each of a plurality of light-receiving regions 201, and a calibration operation may be performed based on intensity of light output by the optical detector. In the calibration operation, weight data applied to each of the plurality of light-receiving regions 201 by the optical detector, or a gain of a circuit detecting intensity of light in the optical detector may be adjusted. In an example implementation, weight data may be generated in the form of offset data.

Thereafter, referring to FIG. 4, a sensor device 300 according to an example implementation may include a body 310 providing a plurality of light-receiving regions 301A-301M, a plurality of optical members 315 connected to the plurality of light-receiving regions 301A-301M, and an optical detector 330 for detecting intensity of light guided by the plurality of optical members 315. The body 310 may include an upper substrate and a lower substrate attached to each other, and a plurality of optical members 315 and an optical detector 330 may be disposed in a space between the upper substrate and the lower substrate.

The number of a plurality of light-receiving regions 301A-301M may be varied in example implementations, and each of a plurality of light-receiving regions 301A-301M may be provided by a hole formed in an upper substrate. The holes providing a plurality of light-receiving regions 301A-301M may be formed in different measurement positions in the upper substrate. Accordingly, when plasma is formed on the sensor device 300, light emitted from different positions of the plasma may be incident to the plurality of light-receiving regions 301A-301M.

Each of the plurality of optical members 315 may include a mirror for reflecting light entering the plurality of light-receiving regions 301A-301M in a direction parallel to an upper surface of the body 310, and an optical fiber guiding light to the optical detector 330. The optical detector 330 may detect intensity of light received through each of the plurality of optical members 315 in a specific wavelength band. A wavelength selector for selectively transmitting light in a specific wavelength band may be disposed no a front end of the optical detector 330, and the wavelength selector may be implemented as a grating structure or a plasmonic filter. A wavelength selector may be configured to transmit a wavelength band of light emitted from the plasma of which characteristics may be analyzed using the sensor device 300. For example, a wavelength selector may be configured to transmit light in a wavelength range of hundreds of nanometers to several micrometers.

In a space in the body 310, in addition to the plurality of optical members 315 and an optical detector 330, a selection device 320, a controller 340, a wireless communication unit 350, and a power supply 360 and 370 may be further disposed. The selection device 320 may select the plurality of optical members 315 one by one, and accordingly, light guided to one optical member 315 selected by the selection device 320 may be inserted into the optical detector 330.

The optical detector may include a plurality of light detector devices having a light-receiving surface perpendicular to an optical axis of light output by the selection device 320, and each of a plurality of light detector devices may include photodiodes for generating electric charges in response to light, and a detector circuit for outputting an electrical signal corresponding to electric charges output by the photodiode. An electrical signal output by the detector circuit may be transferred to the controller 340.

The controller 340 may generate raw data representing intensity of light inserted into each of the plurality of light-receiving regions 301A-301M using the electrical signal received from the optical detector 330. For example, the controller 340 may generate raw data including intensity of light according to a wavelength band by matching the raw data to each of the plurality of light-receiving regions 301A to 301M. Accordingly, raw data including intensity of light detected in the plurality of unit wavelength bands for each of a plurality of light-receiving regions 301A to 301M may be generated.

Referring to FIG. 4, the selection device 320, the optical detector 330, the controller 340, the wireless communication unit 350, and the power supply 360 and 370 may be mounted on a circuit substrate 311. The circuit substrate 311 may be attached to a surface of an upper or lower substrate forming the body 310, and a protective film 313 may be disposed between the circuit substrate 311 and the upper or lower substrate. The protective film 313 may be formed of permalloy and may protect components of the sensor device 300 from an external high-temperature environment and an external magnetic field.

Power required for operation of the selection device 320, the optical detector 330, the controller 340 and the wireless communication unit 350 may be supplied by the power supply 360 and 370. The power supply 360 and 370 may include a battery 360 and a charging circuit 370. The charging circuit 370 may include a circuit for charging the battery 360 in a wired or wireless manner. In an example implementation, while the sensor device 300 is inserted into the calibration apparatus and a calibration operation is performed, the charging circuit 370 may charge the battery 360 using power supplied from the calibration apparatus. To this end, the calibration apparatus may include a charging unit for supplying power to the charging circuit 370.

In an example implementation, the calibration apparatus may be connected to the sensor device 300 through a communication method for supplying both data and power, such as a universal serial bus (USB) port. In this case, the calibration apparatus may receive raw data necessary for a calibration operation from the controller 340 through a USB port and may simultaneously supply power to the sensor device 300. Alternatively, a wireless charging device may be embedded in a stage on which the sensor device 300 is seated in the calibration apparatus, and in this case, the calibration operation may be performed simultaneously with the wireless charging of the battery 360.

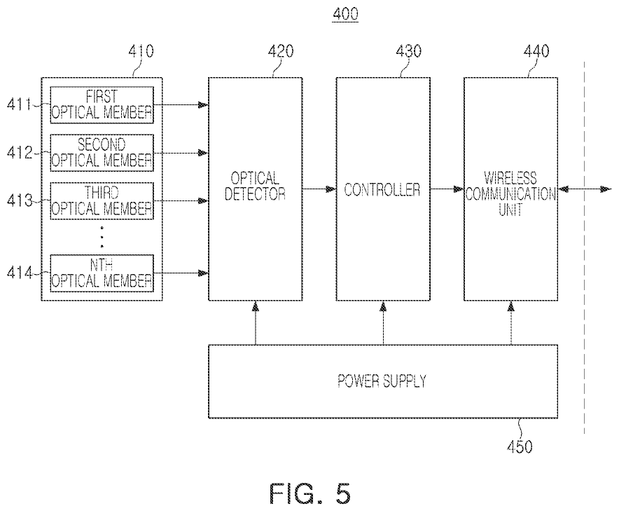

FIG. 5 is a block diagram illustrating an example of a sensor device.

Referring to FIG. 5, a sensor device 400 according to an example implementation may include a plurality of optical members 411-414 (410), an optical detector 420, a controller 430, a wireless communication unit 440 and a power supply 450. When the sensor device is installed in the semiconductor processing apparatus, a plasma may be formed on the sensor device, and the plurality of optical members 410 may receive light emitted from different positions of the plasma.

The optical detector 420 may generate and output an electrical signal representing intensity of light received from each of a plurality of optical members 410. A wavelength selector for selectively passing light in a specific wavelength band may be disposed between the optical detector 420 and the plurality of optical members 410, and the wavelength selector may be configured according to chemical species of gas injected for forming the plasma. For example, a wavelength selector may pass light in the wavelength range of 100 nm to 3 um.

The controller 430 may generate raw data using an electrical signal output by the optical detector 420. The raw data may include data representing intensity of light inserted into a plurality of optical members 410. When the sensor device 400 is taken out of the semiconductor processing apparatus, the controller 430 may transmit raw data to an external entity through the wireless communication unit 440, and for example, the raw data may be transmitted to a host device for controlling the semiconductor processing apparatus. In example implementations, the controller 430 may directly generate characteristic data representing plasma characteristics in a semiconductor processing apparatus using raw data and may transmit the characteristic data to a host device.

However, due to tolerances occurring in the manufacturing process of the sensor device 400 and differences in optical loss (optical loss) appearing in at least a portion of the plurality of optical members 410, the raw data generated by the sensor device 400 reliability may deteriorate. For example, when the first optical member 411 has a greater optical loss than the second optical member 412, even when light of the same intensity enters the first optical member 411 and the second optical member 412, the controller 430 may determine that light having weaker intensity is generated in a first measurement position corresponding to the first optical member 411.

In an example implementation, a calibration operation may be executed in advance before inserting the sensor device 400 to a semiconductor processing apparatus, and in the calibration operation, a deviation of intensity of light output by a plurality of optical members 410 may be eliminated or reduced. For example, the calibration apparatus may include a housing for providing a darkroom space therein, a lighting unit and a stage installed in the darkroom space, and the lighting unit may output light while the sensor device 400 is seated on the stage. In this case, the lighting unit may be controlled such that light of the same intensity may enter the plurality of optical members 410 included in the sensor device 400.

When the optical detector 420 detects intensity of light and the controller 430 outputs raw data, the control device of the calibration apparatus may receive the raw data and may determine intensity of light detected from each of the plurality of optical members 410. For example, when intensity of light is detected weaker in the first optical member 411 than in the second optical member 412, the control device may generate first weight data which may increase intensity of light detected from the first optical member 411 and transmit the data to the controller 430. When the calibration operation ends and the sensor device 400 is inserted into the semiconductor processing apparatus, the controller 430 may reflect first weight data to raw data corresponding to the first optical member 411.

Alternatively, the control device may generate second weight data for reducing intensity of light detected from the second optical member 412 and transmit the data to the controller 430. In this case, the controller 430 may reflect second weight data to the raw data obtained from the second optical member 412 in a state in which the sensor device 400 is inserted into the semiconductor processing apparatus. For example, the first weight data and the second weight data may be offset data.

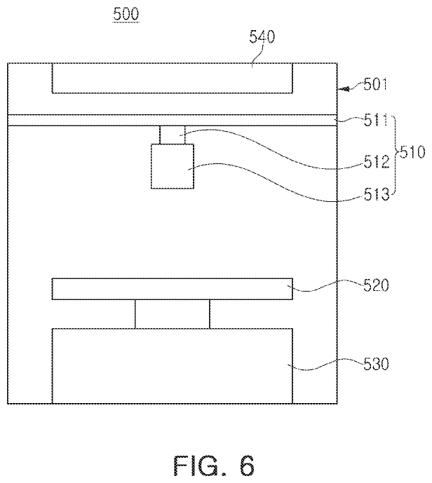

FIGS. 6 to 8 are diagrams illustrating an example of a calibration apparatus.

Referring to FIGS. 6 to 8, a calibration apparatus 500 according to an example implementation may include a housing 501, a lighting unit 510, a stage 520, a temperature controller 530, and a filter unit 540. A darkroom space in which light from the outside is completely blocked may be provided in the housing 501, and a lighting unit 510, a stage 520, a temperature controller 530, and a filter unit 540 may be disposed in the darkroom space. The filter unit 540 may include a fan filter unit (FFU) attached to a ceiling of the housing 501, and may maintain the darkroom space in the housing 501 in a clean room state.

The lighting unit 510 may include a fixing portion 511, a driving portion 512 and a light source unit 513, and the light source unit 513 may output light in a downward direction in which the stage 520 is disposed. The driving portion 512 may connect the fixing portion 511 to the light source unit 513, and may supply driving power to the light source unit 513 for light emitting operation. Also, the driving portion 512 may move while being attached to the fixing portion 511, and accordingly, a position in which the light source unit 513 emits light may be changed within the darkroom space.

In stage 520, a sensor device, which is a target of calibration operation, may be seated. When the sensor device is seated on and fixed to the stage 520, the calibration apparatus 500 may drive the lighting unit 510 and may irradiate light to the sensor device.

In an example implementation illustrated in FIG. 6, the temperature controller 530 may be disposed below the stage 520, but an example implementation thereof is not limited thereto. For example, the temperature controller 530 may be attached to a sidewall of the housing 501 providing a darkroom space, or may be attached to the ceiling of the housing 501 together with the filter unit 540.

The temperature controller 530 may adjust a temperature of the darkroom space in consideration of an internal environment of the semiconductor processing apparatus into which the sensor device seated on the stage 520 is inserted after the calibration operation. For example, when the sensor device is inserted into the semiconductor processing apparatus performing processes such as etching and deposition using plasma, the temperature controller 530 may increase the temperature of the darkroom space to a temperature much higher than room temperature, which may be to reflect the influence of operation properties of the optical members, the optical detectors, and the controllers included in the sensor device from a high-temperature environment to the calibration operation.

A wavelength band of light output by the lighting unit 510 may also be determined in consideration of plasma formed in a semiconductor processing apparatus into which a sensor device is inserted after the calibration operation. As an example, the light source unit 513 may include a light source for outputting light in a wavelength band of hundreds of nanometers to several micrometers, and a wavelength selector for selectively passing only a specific wavelength band from light output by the light source unit 513 may also be included in the lighting unit 510. In other words, the lighting unit 510 and the temperature controller 530 may be controlled such that the internal environment of the semiconductor processing apparatus into which the sensor device is inserted after the calibration operation may be implemented as similarly as possible.

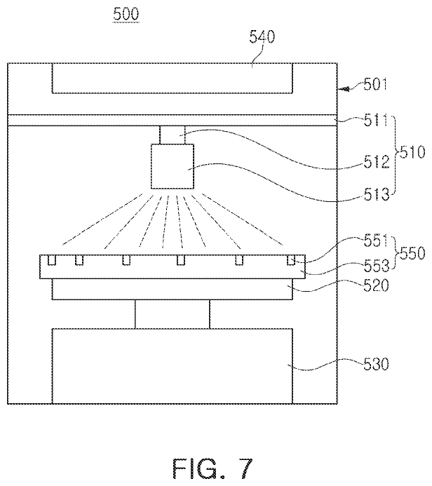

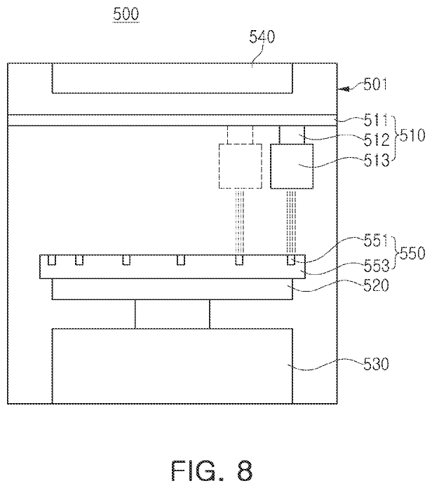

Also, the lighting unit 510 may be controlled such that light of the same intensity may enter a plurality of light-receiving regions provided to different measurement positions in the sensor device. By controlling the lighting unit 510 to output light of the same intensity to the plurality of light-receiving regions as described above, accuracy of the calibration operation for the sensor device may be improved, which will be described in greater detail with reference to FIGS. 7 and 8.

Referring to FIGS. 7 and 8, a sensor device 550 seated on a stage 520 may include a plurality of light-receiving regions 551 and a body 553. The sensor device 550 may be disposed on an upper surface of the stage 520 such that the plurality of light-receiving regions 551 may oppose the lighting unit 510. The sensor device 550 may be fixed and coupled to the upper surface of the stage 520 by adsorption.

First, in an example implementation illustrated in FIG. 7, the lighting unit 510 may output light in a state in which the lighting unit 510 is disposed close to a center of the sensor device 550 in a direction parallel to the upper surface of the sensor device 550. The lighting unit 510 may emit light at a sufficiently wide angle such that light of the same intensity may flow into the plurality of light-receiving regions 551 provided in different measurement positions of the sensor device 550. Alternatively, the light source unit 513 of the lighting unit 510 may be implemented as a surface light source for emitting light on a plane parallel to the upper surface of the sensor device 550.

In an example implementation illustrated in FIG. 8, during the calibration operation, the position of the light source unit 513 in the lighting unit 510 may be changed. As illustrated in FIG. 8, by adjusting positions of the driving portion 512 and the light source unit 513 other than the fixing portion 511, light may be individually incident to each of the plurality of light-receiving regions 551. However, light may be simultaneously incident to two or more light-receiving regions 551 disposed adjacent to each other among the plurality of light-receiving regions 551. In an example implementation illustrated in FIG. 8, the lighting unit 510 may emit light at a narrow angle such that light may be incident to only one light-receiving region 551 or a small number of light-receiving regions 551 at a time.

Also, during the calibration operation, the lighting unit 510 and also the stage 520 may move together to individually allow light to be incident to each of the plurality of light-receiving regions 551. For example, in a state in which the sensor device 550 is fixed to the stage 520, light may be individually incident to each of the plurality of light-receiving regions 551 by rotating the stage 520.

The sensor device 550 may generate raw data by detecting intensity of light incident to the plurality of light-receiving regions 551 and may transmit the intensity to a control device of the calibration apparatus 500. The sensor device 550 may transmit raw data to the control device through wireless communication or may transmit the raw data to the control device through wired communication such as a USB port. When the sensor device 550 is connected to the calibration apparatus 500 through a USB port, the sensor device 550 may receive power required for an operation of detecting intensity of light entering the plurality of light-receiving regions 551 from the USB port.

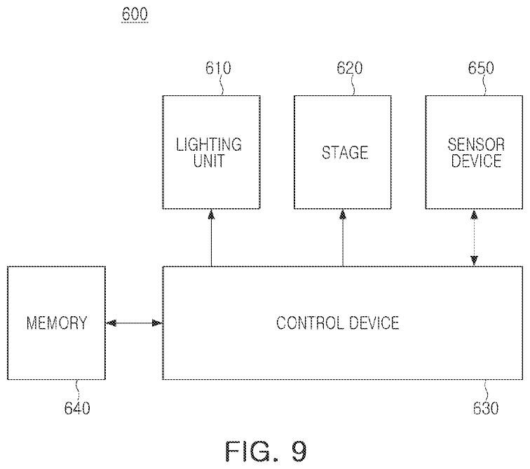

FIG. 9 is a block diagram illustrating an example of a calibration apparatus.

Referring to FIG. 9, a calibration apparatus 600 according to an example implementation may include a lighting unit 610, a stage 620, a control device 630, and a memory 640, and a sensor device 650, which is an object of calibration operation, may be inserted to the calibration apparatus 600. The lighting unit 610 and the stage 620 may be disposed in the darkroom space provided in the housing of the calibration apparatus 600, and the sensor device 650 may be seated on the stage 620.

The control device 630 may control operation of the lighting unit 610, the stage 620 and the sensor device 650. For example, the control device 630 may control the lighting unit 610 to output light, and may move the lighting unit 610 and the stage 620 such that light output by the lighting unit 610 may be incident to at least one of a plurality of light-receiving regions included in the sensor device 650. As in an example implementation illustrated in FIG. 8, the control device 630 may control the lighting unit 610 and the stage 620 such that light may be irradiated to each of the plurality of light-receiving regions at least once.

Hereinafter, assuming that the first to eighth light-receiving regions are included in the sensor device 650 for ease of description, the control device 630 may adjust positions of the lighting unit 610 and the stage 620 such that light output by the lighting unit 610 is incident to a first light-receiving region. Thereafter, the control device 630 may adjust the positions of the lighting unit 610 and the stage 620 such that light output by the lighting unit 610 may be incident to the second light-receiving region. The control device 630 may control the lighting unit 610 and the stage 620 such that light may be radiated at least once to each of the first to eighth light-receiving regions as described above. As described above, light of the same intensity may enter each of the first to eighth light-receiving regions.

The sensor device 650 may detect intensity of light entering each of the first to eighth light-receiving regions, and may transmit raw data including intensity of light entering each light-receiving region to the control device 630. In example implementations, the sensor device 650 may transmit raw data including intensity of light in each of the first to eighth light-receiving regions to the control device 630 collectively. Alternatively, in another example implementation, the sensor device 650 may detect intensity of light as light enters one of the first to eighth light-receiving regions, and may transmit light to the control device 630 prior to detecting the entirety of intensities of light in each of the other light-receiving regions.

Intensity of light detected in each of the first to eighth light-receiving regions may be transmitted to the control device 630 in a digital data format. For example, when intensity of light included in the raw data received by the control device 630 is as in Table 1 below, the control device 630 may execute a calibration operation to generate calibration data.

TABLE 1

| Light-receiving region | #1 | #2 | #3 | #4 | #5 | #6 | #7 | #8 |
|---|---|---|---|---|---|---|---|---|
| Intensity of light | 100 | 80 | 90 | 90 | 80 | 90 | 90 | 100 |

When intensity of light included in the raw data is as in Table 1, the control device 630 may select reference intensity and may generate calibration data based on the reference intensity. As an example, when intensity of the weakest detected light is selected as the reference intensity, the calibration data applied to each light-receiving region may be as in Table 2 below. Referring to Table 2, since intensity of the weakest light detected in the second and fifth light-receiving regions is selected as the reference intensity, negative calibration data reducing measurement results for the other light-receiving regions may be generated.

TABLE 2

| Light-receiving region | #1 | #2 | #3 | #4 | #5 | #6 | #7 | #8 |
|---|---|---|---|---|---|---|---|---|
| Intensity of light | 8/10 | 1 | 8/9 | 8/9 | 1 | 8/9 | 8/9 | 8/10 |

When selecting the most frequent value in intensity of light as the reference intensity, calibration data applied to each light-receiving region may be as in Table 3 below. Referring to Table 3, intensity of light detected in the third, fourth and seventh light-receiving regions may be selected as the reference intensity. As for the first, sixth and eighth light-receiving regions, negative calibration data for decreasing the measurement result may be generated, and for the second and fifth light-receiving regions, positive calibration data for increasing the measurement result may be generated.

TABLE 3

| Light-receiving region | #1 | #2 | #3 | #4 | #5 | #6 | #7 | #8 |
|---|---|---|---|---|---|---|---|---|
| Intensity of light | 9/10 | 9/8 | 1 | 1 | 9/8 | 9/10 | 1 | 9/10 |

Also, differently from the example illustrated in Tables 2 and 3, a representative value of intensity of light obtained from the plurality of light-receiving regions, for example, an average value or a median value, may be selected as the reference intensity. Alternatively, the reference intensity may be determined according to specifications of the lighting unit 610 included in the calibration apparatus 600, regardless of intensity of light obtained from the plurality of light-receiving regions. For example, the control device 630 may determine the reference intensity by referring to the specifications such as light output of the lighting unit 610.

The calibration data generated as illustrated in Table 2 or Table 3 may be transmitted to the system control apparatus of the system including the calibration apparatus 600. In addition to the calibration apparatus 600, the system control apparatus may control transfer systems or semiconductor processing apparatuses included in the system. After the calibration operation for the sensor device 650 is completed, the system control apparatus may generate correction data by applying the calibration data to raw data collected by the sensor device 650 inserted into the semiconductor processing apparatus. The system control apparatus may generate result data representing characteristics of plasma formed in the semiconductor processing apparatus using the correction data.

In an example implementation, the system control apparatus may receive calibration data from the calibration apparatus 600 or the sensor device 650 before the calibration operation for the sensor device 650 is completed and the sensor device 650 is taken out of the calibration apparatus 600. Also, in an example implementation, the system control apparatus may receive calibration data after the calibration operation is completed and the sensor device 650 is taken out of the calibration apparatus 600. For example, calibration data may be transmitted to a system control apparatus while the sensor device 650 is housed in a FOUP. In this case, the FOUP may be in a state of being transferred by a transfer system or in a state of being seated in a specific device, for example, an equipment front end module (EFEM).

Also, in an example implementation, when the calibration operation is completed, the calibration data may be stored in the memory 640 of the calibration apparatus 600. When the sensor device 650 is inserted into the semiconductor processing apparatus, and raw data is generated by detecting intensity of light emitted from plasma formed in the semiconductor processing apparatus, the sensor device 650 may be returned to the calibration apparatus 600 again. The control device 630 may generate correction data by applying calibration data to the raw data generated by the sensor device 650, and may generate result data for analyzing characteristics of plasma based on the correction data. For example, the result data may be formed in an image data format.

Differently from the description described with reference to Tables 1 to 3, only one light-receiving region may be formed in the sensor device 650. In this case, the calibration apparatus 600 may irradiate light twice or more to the light-receiving region, and in example implementations, the calibration apparatus 600 may drive the lighting unit 610 with different light outputs and may irradiate light to the light-receiving region two time or more. When the sensor device 650 generates raw data including intensity of light, the control device 630 may generate calibration data by comparing light output of the lighting unit 610 with intensity of light detected by the sensor device 650. In this case, the reference intensity for determining whether the sensor device 650 accurately detects intensity of light may be determined according to the specification of the lighting unit 610.

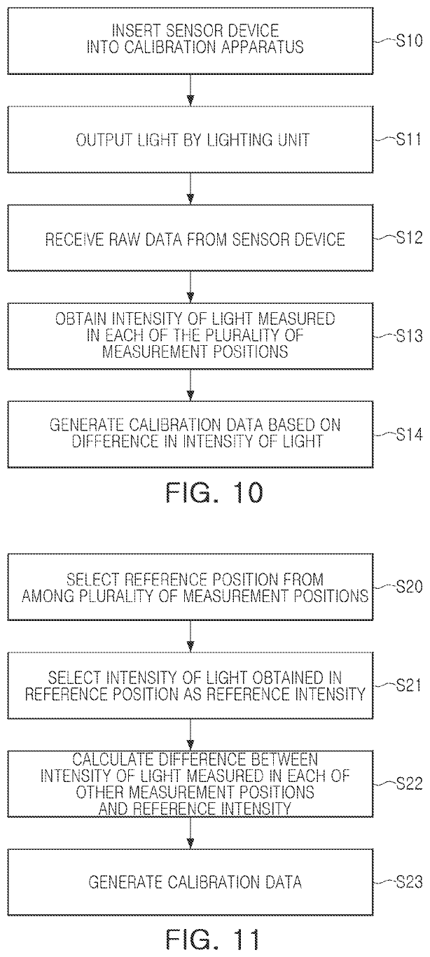

FIGS. 10 and 11 are flowcharts illustrating operations of an example of a calibration apparatus.

First, referring to FIG. 10, the operation of the calibration apparatus according to an example implementation may start with inserting a sensor device into a calibration apparatus (S10). The sensor device may be configured to be inserted into a semiconductor processing apparatus performing a semiconductor process such as deposition, etching, and annealing using plasma. The sensor device may have the same shape as those of a mask substrate, a wafer, and a display mother substrate, which are objects of semiconductor process, and may include a plurality of light-receiving regions into which light emitted from plasma enters. The plurality of light-receiving regions may be provided in different measurement positions in the sensor device.

Each of the plurality of light-receiving regions may be connected to an optical detector through an optical member such as an optical fiber. An optical detector may detect intensity of light in a specific wavelength band. Since a wavelength band of the light emitted from the plasma may be changed by chemical species of gas supplied to the semiconductor processing apparatus to form the plasma, by inserting the sensor device and detecting intensity of the light emitted from the plasma, characteristics such as thickness and density distribution of plasma may be determined. By adjusting control variables of the actual semiconductor process which the semiconductor processing apparatus performs on the wafer based on the characteristics of the plasma obtained by inserting the sensor device, yield of the semiconductor process may be increased.

However, since the plurality of light-receiving regions are formed in different measurement positions in the sensor device and are connected to the optical detector by a plurality of optical members, even when light of the same intensity is incident, intensity of light may be detected differently for at least a portion of the plurality of light-receiving regions. In an example implementation, by inserting a sensor device into the calibration apparatus in advance and executing a calibration operation for compensating for a difference in sensitivity of detecting intensity of light in each of the plurality of light-receiving regions, reliability of operation of analyzing plasma characteristics may be improved using the sensor device.

A darkroom space in which external light is completely blocked may be provided in the calibration apparatus into which the sensor device is inserted. Also, a lighting unit for artificially outputting light may be installed in the calibration apparatus. When the sensor device is inserted into the calibration apparatus, the lighting unit may output light (S11), and light output by the lighting unit may enter the plurality of light-receiving regions of the sensor device. The plurality of optical members connected to the plurality of light-receiving regions may guide incident light to an optical detector.

When the optical detector detects intensity of light inserted into each of the plurality of light-receiving regions, a controller of the sensor device may generate raw data and may transmit the data to the control device of the calibration apparatus (S12). The control device may analyze the raw data to obtain intensity of light measured in each of the plurality of measurement positions in which the plurality of light-receiving regions are disposed (S13), and may generate calibration data using the analysis (S14).

For example, the optical detector may include a plurality of light detector devices, and each of the plurality of light detector devices may include photodiodes for generating electric charges in response to light and a detector circuit for converting electric charges output by the photodiode into an electrical signal such as voltage. An electrical signal output by the detector circuit may be converted into digital data by the controller of the sensor device.

In an example implementation, calibration data may be generated in the form of offset data applied to digital data generated by the controller in the sensor device. Alternatively, in another example implementation, the calibration data may be generated as data for adjusting gain of a detector circuit in each of the plurality of light detector devices.

Thereafter, an operation of generating calibration data will be described in greater detail with reference to FIG. 11. Referring to FIG. 11, the control device of the calibration apparatus may select a reference position from among the plurality of measurement positions by referring to raw data received from the sensor device (S20).

As described above, the plurality of light-receiving regions may be provided to the plurality of measurement positions defined in the sensor device, and when the sensor device is inserted into the calibration apparatus, light of the same intensity may be irradiated to each of the plurality of light-receiving regions. The sensor device may generate raw data by detecting intensity of light irradiated to each of the plurality of light-receiving regions. For example, intensity of light detected by a plurality of measurement positions or a plurality of light-receiving regions may be matched with the raw data and may be included in the raw data. The control device may receive the raw data and may select a reference position from among the plurality of measurement positions.

The reference position may be selected in various manners. For example, the control device may randomly select a reference position without special criteria. Also, the control device may select the measurement position in which intensity of light is detected the weakest as the reference position, or the measurement position closest to a center of the sensor device may be selected as the reference position.

When the reference position is selected, the control device may select intensity of light obtained in the reference position as the reference intensity (S21). However, in example implementations, the control device may directly determine the reference intensity without selecting the reference position from among the plurality of measurement positions. For example, the control device may determine the most frequent value of intensity of light measured in the plurality of measurement positions as the reference intensity. Alternatively, regardless of the sensor device, the reference intensity may be determined according to the specification of a lighting unit for radiating light to the sensor device.

When the reference intensity is determined, the other measurement positions in which the reference intensity and other light intensities are detected may be determined, and the difference between intensity of light measured in each of the other measurement positions and the reference intensity may be calculated (S22). The control device may generate calibration data based on the difference between intensity of light and the reference intensity measured in each of the other measurement positions (S23).

For example, for the first measurement position in which intensity of light stronger than the reference intensity is detected, the control device may generate first calibration data. The first calibration data may include data for reducing a gain of an optical detector when the sensor device selects a first measurement position from among the plurality of measurement positions to detect intensity of light. Also, in an example implementation, the first calibration data may include weight data for reducing data generated by the sensor device selecting a first measurement position and detecting intensity of light.

For example, the control device may generate second calibration data for a second measurement position in which intensity of light weaker than the reference intensity is detected. The second calibration data may include data for increasing the gain of an optical detector when the sensor device selects a second measurement position from among the plurality of measurement positions to detect intensity of light. Also, in an example implementation, the second calibration data may include weight data for increasing data generated by the sensor device detecting intensity of light by selecting the second measurement position.

When the calibration data is formed as data for adjusting the gain of an optical detector, the calibration data may be transmitted to the sensor device and may be stored in an internal memory of the sensor device. The sensor device may change the gain of the optical detector when detecting intensity of light inserted into each of the plurality of measurement positions by referring to the calibration data stored in the internal memory.

For example, the calibration data formed as weight data may be stored in the memory accessible by a system control apparatus for controlling a system including the semiconductor processing apparatus and the calibration apparatus. When the sensor device is inserted into the semiconductor processing apparatus and collects raw data and is drawn out again, the system control apparatus may apply calibration data to the raw data collected by the sensor device and may analyze characteristics of the plasma. However, calibration data formed as weight data may also be stored in the internal memory of the sensor device and transmitted to the system control apparatus by the sensor device.

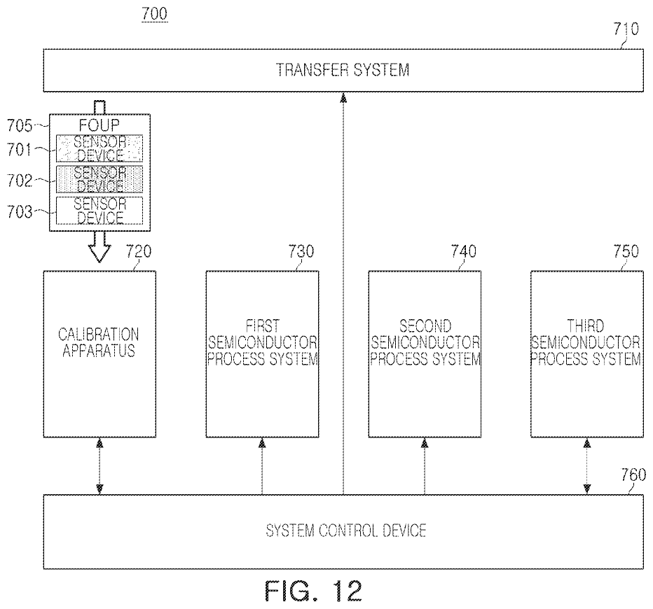

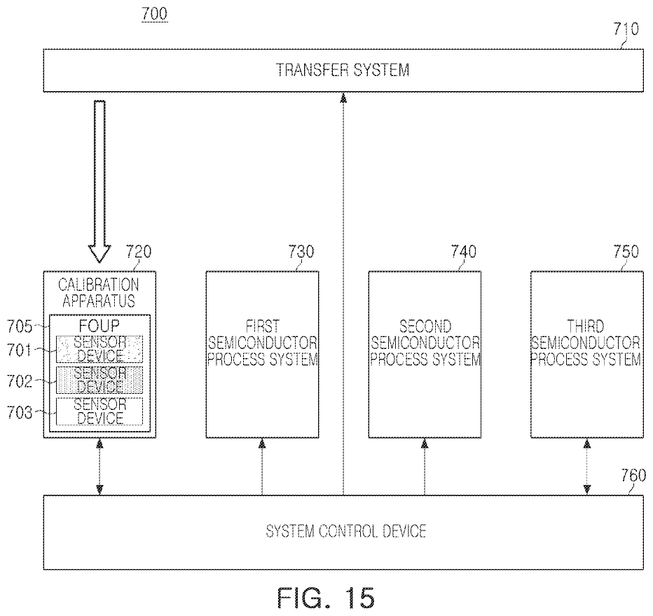

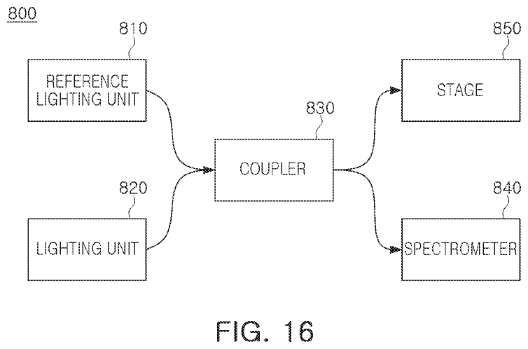

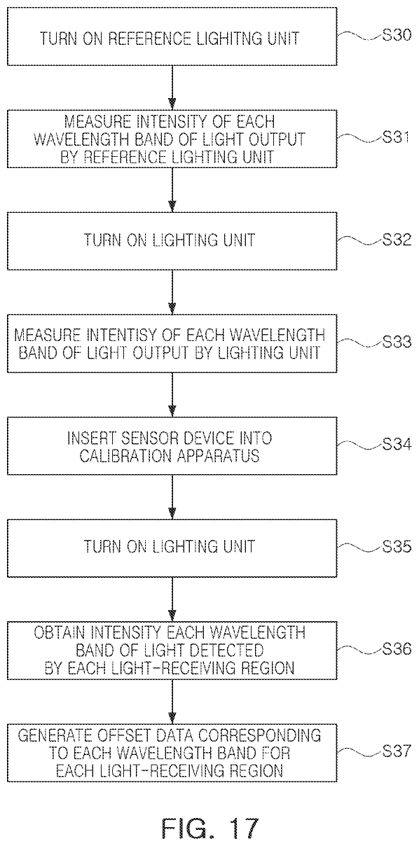

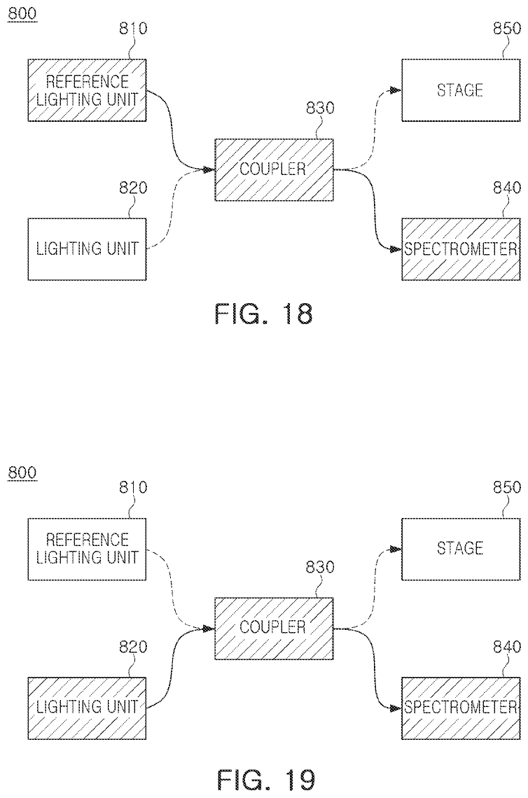

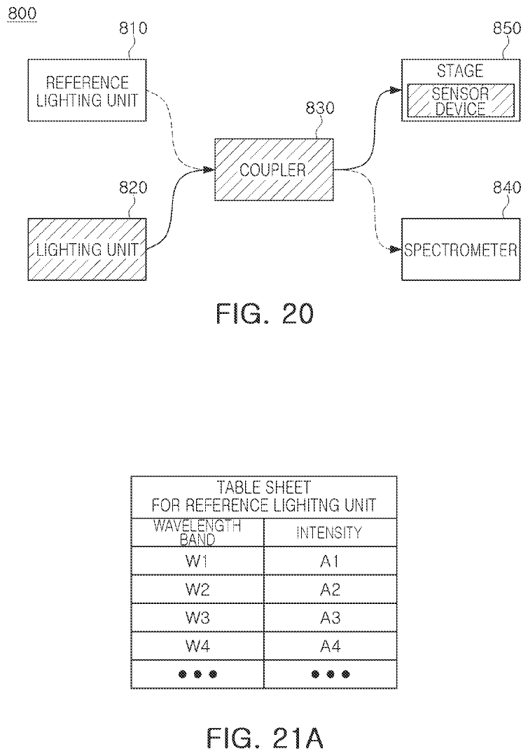

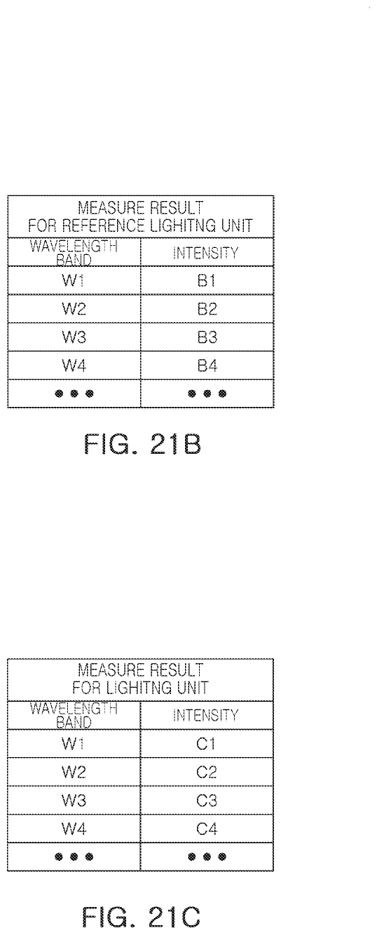

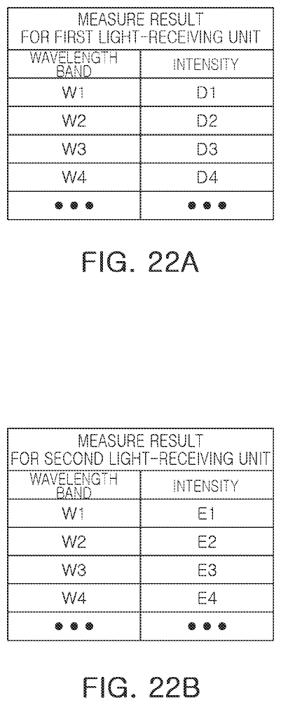

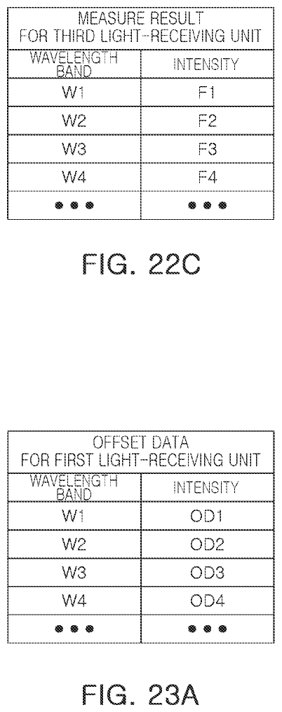

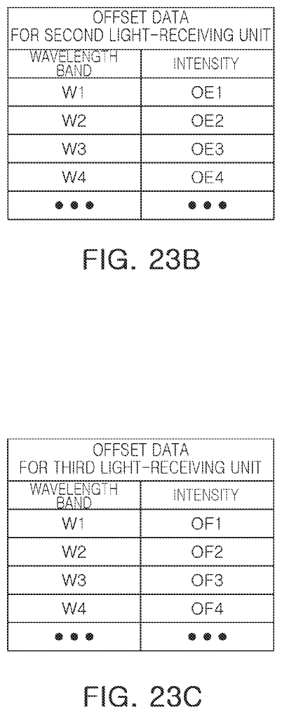

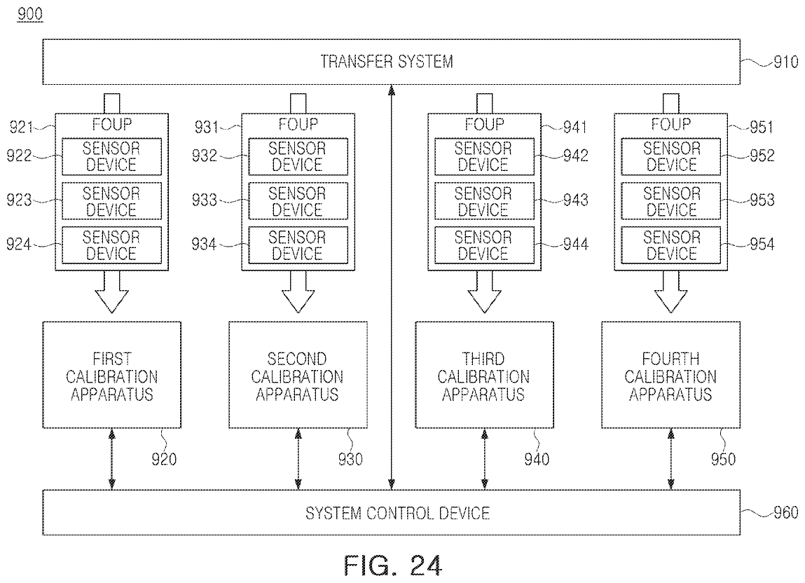

FIGS. 12 to 15 are diagrams illustrating operations of an example of a calibration apparatus.

In an example implementation illustrated in FIGS. 12 to 15, a system 700 may include a transfer system 710, a calibration apparatus 720, and first to third semiconductor process systems 730-750. In the system 700, process targets such as a wafer, a mask substrate, and a mother substrate for display and the sensor devices 701-703 may be transferred between the calibration apparatus 720 and first to third semiconductor process systems 730-750 in a state of being stored in containers such as a FOUP 705. The transfer system 710 for transferring containers such as the FOUP 705 may include a robot or overhead hoist transport (OHT).

In an example implementation, each of the first to third semiconductor process systems 730 to 750 may be implemented as described above with reference to FIG. 1. For example, each of the first to third semiconductor process systems 730-750 may include a wafer transfer device in which the FOUP 705 transferred by the transfer system 710 is seated, a load-lock chamber in which the wafer transfer device receives the wafer taken out by the FOUP 705, and a transfer chamber for transferring the wafer received from the load-lock chamber to the semiconductor processing apparatus. Each of the first to third semiconductor process systems 730-750 may include at least one semiconductor processing apparatus.

In an example implementation, before performing a semiconductor process for a wafer, a mask substrate, and a display mother substrate, the sensor device may be inserted and may determine characteristics of plasma formed in the semiconductor processing apparatus, and a thickness and density of the plasma may be optimally controlled based on this. Accordingly, yield of the semiconductor process may be improved.

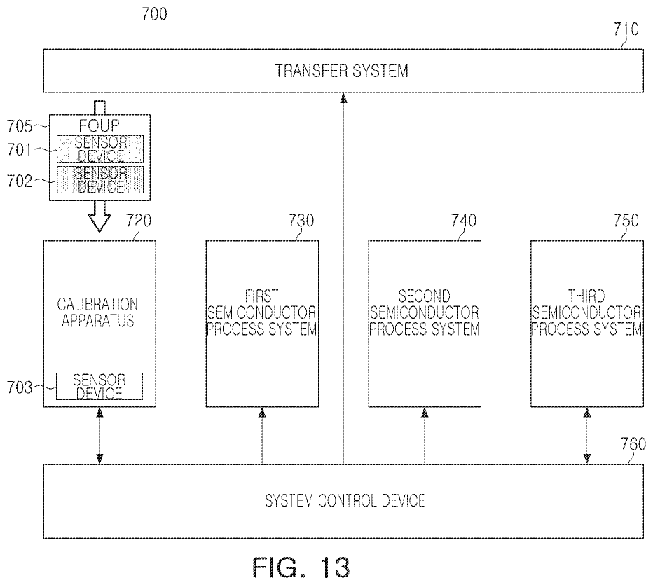

Referring to FIGS. 12 and 13, before being inserted into the semiconductor processing apparatus, the FOUP 705 including sensor devices 701-703 may be inserted into the calibration apparatus 720 by the transfer system 710. The calibration apparatus 720 may provide a darkroom space therein, and a lighting unit and stage may be installed in the darkroom space. In an example implementation illustrated in FIG. 13, a third sensor device 703 is inserted into the calibration apparatus 720, and the third sensor device 703 may be seated on a stage.

A lighting unit may output light to the third sensor device 703 seated on the stage. For example, the lighting unit may output light of the same intensity to the plurality of measurement positions included in the third sensor device 703. However, in example implementations, the third sensor device 703 may include only one measurement position. The third sensor device 703 may generate raw data by detecting intensity of light entering the plurality of measurement positions, and may transmit the raw data to the control device of the calibration apparatus 720.

The control device of the calibration apparatus 720 may determine intensity of light detected in each of the plurality of measurement positions based on raw data from the third sensor device 703 and may calculate a deviation of intensity of light. When there is no deviation of intensity of light or deviation is relatively low, the calibration apparatus 720 may not perform a calibration operation. When deviation of intensity of light is large in at least a portion of the plurality of measurement positions, the calibration apparatus 720 may execute a calibration operation and may generate calibration data for eliminating or reducing the deviation of intensity of light. As described above, calibration data may be generated as weight data or data for adjusting a gain of an optical detector included in the third sensor device 703.

When the calibration data is generated as weight data, the calibration data may be transmitted to the system control apparatus 760. For example, calibration data may be transmitted to the system control apparatus 760 by the calibration apparatus 720 while the third sensor device 703 is inserted into the calibration apparatus 720. Alternatively, after the third sensor device 703 is taken out of the calibration apparatus 720, the third sensor device 703 may be transmitted to the system control apparatus 760 by the third sensor device 703 or the FOUP 705.

When calibration data is generated as data for adjusting the gain of an optical detector, the calibration apparatus 720 may store the calibration data in the third sensor device 703. The third sensor device 703 may generate raw data by detecting intensity of light output by the lighting unit again while adjusting the gain of the optical detector using the calibration data, and the calibration apparatus 720 may determine whether calibration data is appropriately generated by referring to newly generated raw data.

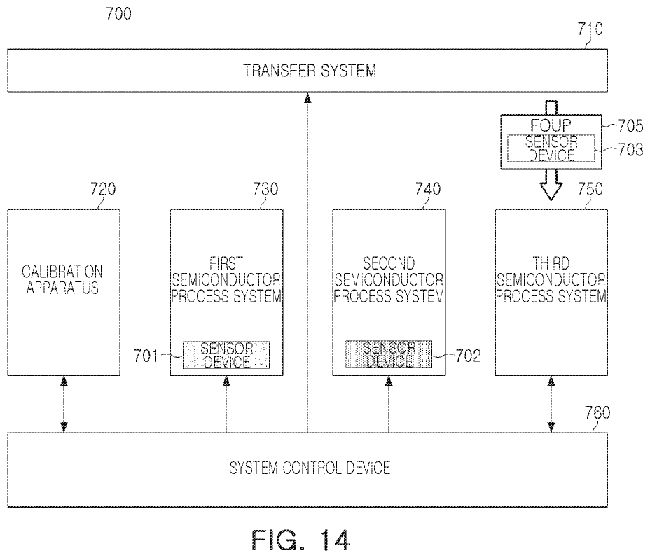

When the calibration operation is completed, the sensor devices 701-703 may be inserted into a target process system among the first to third semiconductor process systems 730 to 750. Referring to FIG. 14, the first sensor device 701 may be inserted into the first semiconductor process system 730, the second sensor device 702 may be inserted into the second semiconductor process system 740, and the third sensor device 703 may be inserted into the third semiconductor process system 750. The transfer system 710 may transfer the FOUP 705 to the first semiconductor process system 730, and the wafer transfer device of the first semiconductor process system 730 may remove the first sensor device 701 from the FOUP 705 and may insert the device into the semiconductor processing apparatus. Similarly, each of the wafer transfer devices of the second and third semiconductor process systems 740 and 750 may take out the second sensor device 702 and the third sensor device 703 from the FOUP 705 and may insert the devices into the semiconductor processing apparatus. In example implementations, two or more sensor devices 701-703 may be inserted into each of the first to third semiconductor process systems 730 to 750 simultaneously.

When a semiconductor processing apparatus of each of the first to third semiconductor process systems 730-750 is inserted into the sensor devices 701-703, plasma may be generated in the semiconductor processing apparatus, and each of the sensor devices 701-703 may detect intensity of light emitted from the plasma. Each of the sensor devices 701-703 may generate raw data including the detected intensity of light, and may be stored in the FOUP 705 in the state in which the raw data is stored, and the devices may be transferred to the calibration apparatus 720.

When the FOUP 705 is transferred to the calibration apparatus 720, raw data collected by each of the sensor devices 701-703 stored in the FOUP 705 or retrieved from the FOUP 705 may be transmitted to the system control apparatus 760. However, in example implementations, after the sensor devices 701-703 collect raw data, in the state in which the sensor devices 701-703 are transferred to a device other than the calibration apparatus 720 by the FOUP 705, for example, the EFEM device, the system control apparatus 760 may transmit raw data.

The system control apparatus 760 may determine characteristics of the plasma formed in each semiconductor processing apparatus of the first to third semiconductor process systems 730-750, for example, a thickness and density of the plasma by referring to the raw data received from the sensor devices 701-703. For example, when it is determined based on the raw data collected by the first sensor device 701 that density of plasma is non-uniformly formed depending on the positions in the semiconductor processing apparatus of the first semiconductor process system 730, the system control apparatus 760 may adjust control parameters of the semiconductor processing apparatus of the first semiconductor process system 730. For example, the control variable adjusted by the system control apparatus 760 may include a gap between upper and lower electrodes included in the semiconductor processing apparatus, bias power supplied to the semiconductor processing apparatus, and an internal temperature of the semiconductor processing apparatus.

FIG. 16 is a block diagram illustrating a calibration apparatus according to an example implementation.

Referring to FIG. 16, a calibration apparatus 800 according to an example implementation may include a reference lighting unit 810, a lighting unit 820, a coupler 830, a spectrometer 840, and a stage 850. The reference lighting unit 810, the lighting unit 820, the coupler 830, the spectrometer 840, and the stage 850 may be installed in the darkroom space provided in a housing of the calibration apparatus 800.

The reference lighting unit 810 and the lighting unit 820 may be coupled to the coupler 830, and the coupler 830 may transfer light output from one of the reference lighting unit 810 and the lighting unit 820 to the spectrometer 840 or the stage 850. The reference lighting unit 810 may include a light source outputting light according to CIE international standards, and may output reference light for a calibration operation of a sensor device according to an example implementation. Intensity of each wavelength band of the reference light output by the reference lighting unit 810 may be provided in the form of a reference table sheet.

The coupler 830 may transfer reference light output by the reference lighting unit 810 to the spectrometer 840. The spectrometer 840 may detect intensity of each wavelength band of reference light. Intensity of reference light for each wavelength band detected by the spectrometer 840 may be an intensity reflecting efficiency of the coupler 830 and a loss of a light transfer path between the reference lighting unit 810 and the spectrometer 840. Accordingly, as compared to intensity of each wavelength band provided in the reference table sheet, different values may appear.

The calibration apparatus 800 may calculate a first difference between the intensity written on the reference table sheet for each wavelength band and the intensity actually detected by the spectrometer 840 of the reference light output by the reference lighting unit 810. Thereafter, the coupler 830 may transfer light output by the lighting unit 820 to the spectrometer 840, and the spectrometer 840 may detect intensity of light output by the lighting unit 820 by each wavelength band. The calibration apparatus 800 may calculate a second difference between intensity of light output by the lighting unit 820 for each wavelength band and intensity of the reference light output by the reference lighting unit 810.

Thereafter, in a state in which the sensor device is seated on the stage 850 and the lighting unit 820 is turned on, light output by the lighting unit 820 may incident to each of light-receiving regions of the sensor device by the coupler 830. The calibration apparatus 800 may obtain intensity of light detected by wavelength band in each light-receiving region. The calibration apparatus 800 may calculate a third difference by comparing intensity of light detected by wavelength band in each light-receiving region with intensity of light detected by wavelength band by the spectrometer 840 in a state in which the lighting unit 820 is turned on.

The calibration apparatus 800 may generate offset data for each wavelength band for each light-receiving region using the first to third differences. Offset data may be weight data added to intensity of light detected by wavelength band in each light-receiving region by the sensor device actually inserted into a chamber performing a semiconductor process.

By generating weight data for each light-receiving region of the sensor device using the reference lighting unit 810, which outputs reference light according to international standards, as described above, weight data that may accurately compensate for differences in characteristics of the plurality of sensor devices may be generated. Also, by simultaneously performing a calibration operation for the sensor device using two or more calibration apparatuses, efficiency of the calibration operation may be increased.

FIG. 17 is a flowchart illustrating operation of a calibration apparatus according to an example implementation. FIGS. 18 to 20 are diagrams illustrating operation of a calibration apparatus according to an example implementation.

Hereinafter, operation of the calibration apparatus according to an example implementation will be described with reference to FIGS. 17 to 20. Operation of the calibration apparatus 800 according to an example implementation may start with the reference lighting unit 810 being turned on (S30). As described above, the reference lighting unit 810 may output reference light having intensity of each wavelength band in accordance with CIE international standards.

As illustrated in FIG. 18, the spectrometer 840 may measure intensity of each wavelength band of light output by the reference lighting unit 810 (S31). Thereafter, as illustrated in FIG. 19, the reference lighting unit 810 may be turned off, the lighting unit 820 may be turned on (S32), and the spectrometer 840 may measure intensity of each wavelength band of light output by the lighting unit 820 (S33).

Thereafter, as illustrated in FIG. 20, the sensor device 860 may be inserted into the calibration apparatus 800 and may be seated on the stage 850 (S34). When the sensor device 860 is seated on the stage 850, the lighting unit 820 may be turned on (S35), and light output by the lighting unit 820 may incident to each of the light-receiving regions included in the sensor device 860. In an example implementation, light output by the lighting unit 820 may be incident to the light-receiving regions simultaneously, or may be incident to at least a portion of the light-receiving regions in order.

The sensor device 860 may detect intensity of each wavelength band of light incident to each light-receiving region, and the calibration apparatus 800 may obtain intensity of light detected by the sensor device 860 (S36). The calibration apparatus 800 may generate offset data corresponding to each wavelength band for each light-receiving region of the sensor device 860 (S37). The offset data generated in operation S37 may be reflected in data collected when the sensor device 860 is inserted into a chamber which may generate plasma and may perform a semiconductor process.

In an example implementation, by performing a calibration operation for each light-receiving region of the sensor device 860 using a reference lighting unit 810 outputting light conforming to international standards, offset data in which differences in characteristics of each light-receiving region of sensor device 860 and differences in characteristics of the lighting unit 820 used in a calibration operation are reflected may be generated. The reference lighting unit 810, outputting light conforming to international standards, may have a relatively short lifespan as compared to the lighting unit 820, which outputs general light, and accordingly, by implementing the calibration apparatus 800 to include both reference the lighting unit 810 and the lighting unit 820, issues related to the short lifespan of the reference lighting unit 810 may be addressed.

FIGS. 21A to 21C, FIGS. 22A to 22C, and FIGS. 23A to 23C are diagrams illustrating operation of a calibration apparatus according to an example implementation.

FIG. 21A may be a reference table sheet on which intensity of each wavelength band of the reference light output by the reference lighting unit included in the calibration apparatus is written. For example, a reference table sheet may be data provided by a manufacturer of the reference lighting unit. Referring to FIG. 21A, the reference light may have a first reference intensity A1 in a first wavelength band W1, a second reference intensity A2 in a second wavelength band W2, a third reference intensity A3 in a third wavelength band W3, and a fourth reference intensity A4 in a fourth wavelength band W4. The reference light may further include other wavelength bands in addition to the first to fourth wavelength bands W1-W4.

FIG. 21B may indicate the result of measuring intensity of each wavelength band of reference light output by the reference lighting unit included in the calibration apparatus using a spectrometer. In other words, FIG. 21B may indicate intensity of light for each wavelength band measured by the spectrometer while the reference lighting unit mounted on the calibration apparatus is turned on and output reference light is input to the spectrometer through the coupler.

Referring to FIG. 21B, the spectrometer may detect intensity of reference light as a first reference measurement intensity B1 in the first wavelength band W1, may detect intensity of reference light as a second reference measurement intensity B2 in the second wavelength band W2, may detect intensity of reference light as a third reference measurement intensity B3 in the third wavelength band W3, and may detect intensity of reference light as a fourth reference measurement intensity B4 in the fourth wavelength band W4. Due to losses occurring in a light transfer path between the reference lighting unit and the spectrometer, the reference intensity and the reference measurement intensity may appear different in at least one of the wavelength bands W1-W4.

Thereafter, FIG. 21C may be the result of measuring intensity of each wavelength band of light output by the lighting unit included in the calibration apparatus using a spectrometer. Referring to FIG. 21C, the spectrometer may detect intensity of light output by the lighting unit as the first lighting intensity C1 in the first wavelength band W1, as a second lighting intensity C2 in the second wavelength band W2, as a third lighting intensity C3 in the third wavelength band W3, and as a fourth lighting intensity C4 in the fourth wavelength band W4.

The calibration apparatus may calculate a difference between the reference intensities A1-A4 and the reference measurement intensities B1-B4, and a difference between the reference measurement intensities B1-B4 and the lighting intensities C1-C4, in each of the plurality of wavelength bands W1-W4. For example, the calibration apparatus may calculate a first difference between the first reference intensity A1 and the first reference measurement intensity B1, and a second difference between the first reference intensity measurement intensity B1 and the first lighting C1 in the first wavelength band W1. The results calculated by the calibration apparatus for each wavelength bands W1-W4 may be as in Table 4 below.

TABLE 4

| | |
|---|---|
| First difference | Second difference |

| Wavelength | Calculation | Wavelength | Calculation |
|---|---|---|---|
| band | results | band | results |
| W1 | A1 − B1 = α1 | W1 | B1 − C1 = β1 |
| W2 | A2 − B2 = α2 | W2 | B2 − C2 = β2 |
| W3 | A3 − B3 = α3 | W3 | B3 − C3 = β3 |
| W4 | A4 − B4 = α4 | W4 | B4 − C4 = β4 |
| . . . | . . . | . . . | . . . |

FIGS. 22A to 22C illustrate intensity of light by wavelength band detected by the sensor device for each light-receiving region while light is irradiated to each light-receiving region of the sensor device inserted into the calibration apparatus using a lighting unit. Referring to FIG. 22A, intensity of light incident to the first light-receiving region may be detected as first to fourth intensities D1-D4 in the first to fourth wavelength bands W1-W4, respectively. Referring to FIG. 22B, intensity of light incident to the second light-receiving region may be detected as first to fourth intensities E1-E4 in the first to fourth wavelength bands W1-W4, respectively. Referring to FIG. 22C, intensity of light incident to the third light-receiving region may be detected as first to fourth intensities F1-F4 in the first to fourth wavelength bands W1-W4, respectively.

The calibration apparatus may calculate a difference between intensity of light detected by wavelength band in each of the plurality of light-receiving regions and the lighting intensities C1-C4 of the lighting unit detected by the spectrometer by wavelength band. For example, the calibration apparatus may obtain calculation results as in Table 5 below.

TABLE 5

| First light- | | Second light- | | Third light- | |
|---|---|---|---|---|---|
| receiving region | | receiving region | | receiving region | |
| Wavelength | Calculation | Wavelength | Calculation | Wavelength | Calculation |
| band | results | band | results | band | results |
| W1 | C1 − D1 = γ1 | W1 | C1 − E1 = δ1 | W1 | C1 − F1 = ε1 |
| W2 | C2 − D2 = γ2 | W2 | C2 − E2 = δ2 | W2 | C2 − F2 = ε2 |
| W3 | C3 − D3 = γ3 | W3 | C3 − E3 = δ3 | W3 | C3 − F3 = ε3 |
| W4 | C4 − D4 = γ4 | W4 | C4 − E4 = δ4 | W4 | C4 − F4 = ε4 |
| . . . | . . . | . . . | . . . | . . . | . . . |

As in Table 5 above, the calibration apparatus may calculate a difference between the light intensities D1-D4, E1-E4, F1-F4 detected for wavelength bands W1-W4 in the light-receiving regions and the lighting intensities C1-C4. As illustrated in FIGS. 23A to 23C, the calibration apparatus may generate offset data for each wavelength band for each of the plurality of light-receiving regions using the calculation results described with reference to Table 4 and Table 5.

Referring to FIG. 23A as an example, first offset data OD1 may be applied to data corresponding to the first wavelength band W1 among pieces of data obtained by detecting intensity of light incident to the first light-receiving region. For example, the first offset data OD1 may be determined as [α1+β1+γ1]. Similarly, in the first light-receiving region, second offset data OD2 may be determined as [α2+β2+γ2], third offset data OD3 may be determined as [α3+β3+γ3], and fourth offset data OD4 may be determined as [α4+β4+γ4].

First to fourth offset data OE1-OE4 may be applied to data generated by detecting intensity of light by wavelength band for light incident to the second light-receiving region. For example, in the second light-receiving region, first offset data OE1 may be determined as [α1+β1+δ1], second offset data OE2 may be determined as [α2+β2+δ2], third offset data OE3 may be determined as [α3+β3+δ3], and fourth offset data OE4 may be determined as [α4+β4+δ4].

First to fourth offset data OF1-OF4 may be applied to data generated by detecting intensity of light by wavelength band for light incident to the third light-receiving region. For example, in the second light-receiving region, first offset data OF1 may be determined as [α1+β1+ε1], second offset data OF2 may be determined as [α2+β2+ε2], third offset data OF3 may be determined as [α3+β3+ε3], and fourth offset data OF4 may be determined as [α4+β4+ε4]. Offset data OD1-OD4, OE1-OE4, and OF1-OF4 as illustrated in FIGS. 23A to 23C may be stored in the calibration apparatus, the sensor device, or a system control device which controls a chamber into which the sensor device is inserted.

When the sensor device is inserted into the chamber after the calibration operation is completed, plasma may be generated in the chamber. The sensor device may generate data by detecting intensity of light emitted from the plasma and incident to the light-receiving region. Thereafter, the offset data OD1-OD4, OE1-OE4, and OF1-OF4 as in the example implementations illustrated in FIGS. 23A to 23C may be reflected in the data generated by the sensor device.

FIG. 24 is a diagram illustrating operation of a calibration apparatus according to an example implementation.

In an example implementation illustrated in FIG. 24, a system 900 may include a transfer system 910, a plurality of calibration apparatuses 920-950, and a system control device 960. In the system 900, process objects such as a wafer, a mask substrate, a mother substrates for display, and a sensor device may be stored in containers such as FOUPs 921, 931, 941, and 951 and may be transferred to calibration apparatuses 920-950.

In an example implementation illustrated in FIG. 24, a calibration operation may be performed individually in the plurality of calibration apparatuses 920-950. For example, while the plurality of sensor devices 922-924 transferred to the first FOUP 921 are inserted into the first calibration apparatus 920 in order, a calibration operation may be performed on the plurality of sensor devices 932-934 transferred to the second FOUP 931 in the second calibration apparatus 930. Similarly, the third calibration apparatus 940 may also receive sensor devices 942-944 from the third FOUP 941 and may perform a calibration operation, and the fourth calibration apparatus 950 may also perform a calibration operation for each of the sensor devices 952-954 transferred to the fourth FOUP 951.

Although the calibration operations are individually performed in the plurality of calibration apparatuses 920-950, according to an example implementation, characteristic deviation of the sensor devices may be reduced. Each of the plurality of calibration apparatuses 920-950 may be configured to include a reference lighting unit outputting light having intensity conforming to international standards, and offset data for each light-receiving region of the sensor device may be generated by wavelength band using the reference lighting unit, two or more calibration apparatuses 920-950 may operate simultaneously. Accordingly, by improving a speed and efficiency of the calibration operation and generating offset data optimized for each sensor device, accuracy of the plasma characteristic measurement operation using the sensor device may be improved.

According to the aforementioned example implementations, a sensor device having the same shape as that of a process target such as a wafer, mask, or mother substrate for display may be provided, and the sensor device inserted into the semiconductor processing apparatus may generate raw data representing characteristics of plasma on the basis of information collected from the plurality of measurement positions. The calibration apparatus according to an example implementation may adjust operation of the sensor device before the sensor device is inserted into the semiconductor processing apparatus, and accordingly, reliability of raw data generated by the sensor device may be improved, and yield of a semiconductor process performed in the semiconductor processing apparatus may be improved.

While this specification contains many specific implementation details, these should not be construed as limitations on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a claimed combination can in some cases be excised from the combination, and the claimed combination may be directed to a subcombination or variation of a subcombination.

While the example implementations have been illustrated and described above, it will be configured as apparent to those skilled in the art that modifications and variations may be made without departing from the scope in the example implementation as defined by the appended claims.

1. A calibration apparatus of a sensor device, the calibration apparatus comprising:
a housing configured to provide a darkroom space by blocking light from outside of the housing;
a lighting unit installed in the darkroom space and configured to output light in a specific wavelength band;
a stage on which the sensor device, is mounted, wherein the stage is installed below the lighting unit in the darkroom space, and wherein the sensor device is configured to detect an intensity of light output by the lighting unit in at least one measurement position; and
a processor configured to receive raw data including the intensity of light measured by the sensor device,
wherein the processor is configured to execute instructions that cause the processor to perform operations comprising generating calibration data for adjusting the intensity of light measured at the at least one measurement position.

2. The calibration apparatus of claim 1, wherein, when the sensor device includes two or more measurement positions, generating the calibration data comprises reducing a difference in intensities of light measured at the two or more measurement positions.

3. The calibration apparatus of claim 2, wherein the operations comprise selecting a reference intensity using the intensities of light measured at the two or more measurement positions, and wherein generating the calibration data is based on differences between intensity of light measured at each measurement position of the two or more measurement positions and the reference intensity.

4. The calibration apparatus of claim 3, wherein the operations comprise:
generating negative calibration data for reducing a measurement result with respect to at least one measurement position in which intensity of light stronger than the reference intensity is measured among the two or more measurement positions; and
generating positive calibration data for increasing a measurement result for at least one measurement position in which intensity of light weaker than the reference intensity is measured among the two or more measurement positions.

5. The calibration apparatus of claim 3, wherein the operations comprise determining one of intensity of light measured in a reference position among the two or more measurement positions, an average value, a minimum value, and a most frequent value of intensities of light measured in the two or more measurement positions.

6. The calibration apparatus of claim 3, wherein the operations comprise determining the reference intensity according to a specification of the lighting unit.

7. The calibration apparatus of claim 1, wherein, when the sensor device includes a single measurement position, generating the calibration data comprises reducing a difference between intensities of light measured two or more times in the single measurement position.

8. The calibration apparatus of claim 1, wherein a wavelength band of light output by the lighting unit is included in a wavelength band of 200 nm to 3 um.

9. The calibration apparatus of claim 1, wherein the processor is configured to move the stage, the lighting unit, or the stage and the lighting unit, such that light output by the lighting unit enters the at least one measurement position.

10. The calibration apparatus of claim 1, further comprising:
a temperature controller configured to control a temperature of the darkroom space,
wherein the operations comprise controlling the temperature controller such that a temperature of the darkroom space matches an internal temperature of a chamber of a semiconductor processing apparatus into which the sensor device is inserted.

11. The calibration apparatus of claim 1, further comprising:
a charging unit configured to charge a battery included in the sensor device.

12. A calibration apparatus of a sensor device, the calibration apparatus comprising:
a lighting unit configured to output light of a same intensity to a plurality of measurement positions included in a sensor device, the sensor device including a lower substrate and an upper substrate opposing the lower substrate, a plurality of optical members configured to guide light entering the plurality of measurement positions formed on the upper substrate, and an optical detector configured to detect intensity of light guided by each optical member of the plurality of optical members;
a stage on which the sensor device is to be mounted; and
a processor configured to be communicatively coupled to the sensor device and configured to receive raw data from the sensor device, the raw data including intensity of light measured by the sensor device in each measurement position of the plurality of measurement positions,
wherein the processor is configured to execute operations comprising generating calibration data such that intensities of light measured at the plurality of measurement positions are equalized.

13. The calibration apparatus of claim 12, wherein the processor is configured to transmit the calibration data to a server for controlling the calibration apparatus and a semiconductor processing apparatus to which the sensor device is inserted, and for performing a semiconductor process.

14. The calibration apparatus of claim 12, wherein the processor comprises memory configured to store the calibration data.

15. The calibration apparatus of claim 12, wherein the sensor device has a same shape as a wafer, a mother substrate for display, or a mask substrate.

16. The calibration apparatus of claim 12, wherein the operations comprise determining one of an average value, a minimum value, and a most frequent value of intensities of light measured in the plurality of measurement positions as reference intensity, and to generate the calibration data based on differences between the reference intensity and intensity of light measured in each measurement position of the plurality of measurement positions.

17. A system, comprising:
a plurality of semiconductor process systems each including a semiconductor processing apparatus configured to form plasma and to perform a semiconductor process;
a transfer system configured to transfer at least one sensor device to the plurality of semiconductor process systems; and
a calibration apparatus including a housing providing a darkroom space, a lighting unit and a stage installed in the darkroom space, wherein the calibration apparatus is configured to perform a calibration operation of reducing a characteristic deviation of a measurement position included in the at least one sensor device, while the at least one sensor device is mounted on the stage and the lighting unit outputs light.

18. The system of claim 17, wherein the transfer system includes a robot, an overhead hoist transport (OHT), or the robot and the OHT.

19. The system of claim 17, further comprising:
a system control apparatus configured to control the plurality of semiconductor process systems, the transfer system, and the calibration apparatus,
wherein the system control apparatus is configured to control a target semiconductor process system based on data collected by inserting the at least one sensor device into the target semiconductor process system among the plurality of semiconductor process systems after the calibration operation is completed.

20. The system of claim 19, wherein, when the calibration operation is completed, the system control apparatus is configured to receive calibration data from the sensor device, the calibration apparatus, or the sensor device and the calibration apparatus before the sensor device is withdrawn from the calibration apparatus.

21.-23. (canceled)
